(19) United States
(12) Patent Application Publication
(10) Pub. No.: US 2019/0249295 A1
(43) Pub. Date: Aug. 15, 2019

(54) AMMONIA PRE-TREATMENT TO PROMOTE AMORPHOUS SILICON ADHESION TO ALUMINUM NITRIDE

(71) Applicant: LAM RESEARCH CORPORATION, Fremont, CA (US)

(72) Inventors: Jon David Sumega, Portland, OR (US); Jeffrey Ryan Simpson, Tualatin, OR (US)

(21) Appl. No.: 16/266,732

(22) Filed: Feb. 4, 2019

Related U.S. Application Data
(60) Provisional application No. 62/626,390, filed on Feb. 5, 2018.

(51) Int. Cl. C23C 16/24; C23C 16/505; C23C 16/02; C23C 16/448; C23C 16/52

(52) U.S. Cl. CPC C23C 16/24; C23C 16/505; C23C 16/52; C23C 16/448; C23C 16/0272

(57) ABSTRACT

A method for depositing an amorphous film includes providing, in a substrate processing chamber, a substrate including an aluminum nitride layer and performing a pre-treatment process to condition an upper surface of the aluminum nitride layer. Performing the pre-treatment process includes supplying a gas mixture including ammonia into the substrate processing chamber and activating plasma within the substrate processing chamber to condition the upper surface of the aluminum nitride layer. The method further includes depositing the amorphous film onto the aluminum nitride layer.

### CROSS-REFERENCE TO RELATED APPLICATIONS

This application claims the benefit of U.S. Provisional Application No. 62/626,390, filed on Feb. 5, 2018. The entire disclosure of the application referenced above is incorporated herein by reference.

### FIELD

The present disclosure relates to depositing amorphous silicon on an aluminum nitride substrate or layer in a substrate processing system.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

During processing of substrates such as semiconductor wafers, various substrate treatments including deposition, patterning, and/or etching are performed. Substrate processing systems for performing deposition typically include a processing chamber with a pedestal. A substrate such as a semiconductor wafer may be arranged on the pedestal. A process gas mixture including one or more precursor gases may be introduced into the processing chamber to deposit film on the substrate. Plasma may be used to activate chemical reactions.

For example, in a chemical vapor deposition (CVD) process, a gas mixture including one or more precursors may be introduced into the processing chamber to deposit film on the substrate. In some substrate processing systems, plasma may be used to activate chemical reactions in a plasma enhanced CVD (PECVD) process. A PECVD process may be used to deposit amorphous carbon and silicon films as hardmasks and/or other applications for etching during subsequent substrate processing steps.

### SUMMARY

A method for depositing an amorphous film includes providing, in a substrate processing chamber, a substrate including an aluminum nitride layer and performing a pre-treatment process to condition an upper surface of the aluminum nitride layer. For example, conditioning the upper surface of the aluminum nitride layer may include removing material including at least one of residual deposition material, atmospheric contamination and native oxides from the upper surface of the aluminum nitride layer. Performing the pre-treatment process includes supplying a gas mixture including ammonia into the substrate processing chamber and activating plasma within the substrate processing chamber to condition the upper surface of the aluminum nitride layer. The method further includes depositing the amorphous film onto the aluminum nitride layer.

In other features, the amorphous film is amorphous silicon. The gas mixture further includes a non-reactive gas. The non-reactive gas is non-destructive to aluminum nitride. The non-reactive gas includes at least one of molecular nitrogen gas, argon gas, and helium gas.

In other features, activating the plasma causes the gas mixture to react with the material on the upper surface of the aluminum nitride layer. Activating the plasma causes the gas mixture to react with the material to form molecules with at least one of nitrogen and hydrogen and components of the material. The material includes at least one of oxygen and carbon. The method further includes purging the substrate processing chamber subsequent to performing the pre-treatment process and prior to depositing the amorphous film.

A system for depositing an amorphous film includes a gas delivery system configured to provide one or more gases to a substrate processing chamber, a radio frequency (RF) generating system configured to activate plasma within the substrate processing chamber, and a controller configured to perform a pre-treatment process to condition an upper surface of an aluminum nitride layer of a substrate. For example, conditioning the upper surface of the aluminum nitride layer may include removing material including at least one of residual deposition material, atmospheric contamination and native oxides from the upper surface of the aluminum nitride layer. To perform the pre-treatment process, the controller is further configured to control the gas delivery system to supply a gas mixture into the substrate processing chamber, wherein the gas mixture includes ammonia and control the RF generating system to activate plasma within the substrate processing chamber to condition the upper surface of the aluminum nitride layer. The controller is further configured to control the gas delivery system to deposit the amorphous film onto the aluminum nitride layer.

In other features of the system, the amorphous film is amorphous silicon. The gas mixture further includes a non-reactive gas. The non-reactive gas is non-destructive to aluminum nitride. The non-reactive gas includes at least one of molecular nitrogen gas, argon gas, and helium gas.

In other features of the system, activating the plasma causes the gas mixture to react with the material on the upper surface of the aluminum nitride layer. Activating the plasma causes the gas mixture to react with the material to form molecules with at least one of nitrogen and hydrogen and components of the material. The material includes at least one of oxygen and carbon. The controller is further configured to control purging of the substrate processing chamber subsequent to performing the pre-treatment process and prior to depositing the amorphous film.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example substrate processing system according to the present disclosure;

FIGS. 2A, 2B, and 2C illustrate an example amorphous silicon film deposition process;

FIGS. 3A, 3B, 3C, and 3D illustrate another example amorphous silicon film deposition process;

FIGS. 4A, 4B, 4C, and 4D illustrate an example amorphous silicon film deposition process including a pre-treatment of an aluminum nitride layer according to the present disclosure; and

FIG. 5 is an example method of performing a pre-treatment process of an aluminum nitride layer and deposition of an amorphous silicon film according to the present disclosure.

In the drawings, reference numbers may be reused to identify similar and/or identical elements.

### DETAILED DESCRIPTION

A plasma enhanced chemical vapor deposition (PECVD) process may be used to deposit an amorphous film, such as an amorphous silicon (a-Si) film, on an underlying layer or substrate. For example, the a-Si film may be deposited on an aluminum nitride (AlN) layer in the manufacturing of a microelectromechanical systems (MEMS) device, such as a film bulk acoustic resonator (FBAR). However, adhesion of the a-Si film to the AlN layer may be unsatisfactory. For example, a non-homogenous surface chemistry of the AlN layer may prevent adequate adhesion between the AlN layer and the a-Si film. Consequently, the a-Si film may easily delaminate (i.e., separate) from the AlN layer.

Accordingly, some processes may deposit an intermediate adhesion layer on the AlN layer to facilitate adhesion of the a-Si film. In one example, a silicon carbide (SiC) adhesion layer may be deposited on the AlN layer and the a-Si film is deposited on the SiC adhesion layer. However, depositing such an adhesion layer typically requires transfer of the substrate to a different processing chamber and increases overall cost and processing time.

One possible cause of inadequate adhesion between the AlN layer and the a-Si film is residual atmospheric or deposition related materials (e.g., atoms and/or molecules) and/or native oxides on surface bonding sites of the AlN layer. The residual materials may include, but are not limited to, oxygen such as terminal oxygen atoms (e.g., native oxides), and/or other materials. For example, the oxygen may prevent uniform nucleation and growth of the a-Si film across the surface of the AlN layer and/or result in a poor adhesion interface between the a-Si film and the AlN layer. An a-Si film deposition system and method according to the principles of the present disclosure implements a pre-treatment process that eliminates the need for an intermediate adhesion layer.

For example, the pre-treatment process includes applying a gas mixture including ammonia to the AlN layer to condition and/or remove surface oxygen (e.g., oxide) remaining on the AlN layer. In one example, the pre-treatment process includes a mixture of ammonia (e.g., NH₃) gas and molecular nitrogen (N₂) gas. NH₃ gas is selected as a reactive gas that is non-destructive with respect to the deposited AlN layer. In other examples, argon (Ar) gas, helium (He) gas, and/or another non-reactive gas may be provided in addition to or instead of the N₂ gas. When the gas mixture including the NH₃ gas is activated by plasma, the activated ammonia gas mixture scavenges and removes the residual oxygen on the surface of the AlN layer. For example, the plasma activated ammonia gas mixture may cause the formation of multiple combinations of molecules including nitrogen, hydrogen, and/or oxygen (as well as other contaminants, such as carbon) that may be subsequently removed from the processing chamber. Consequently, the surface of the AlN layer is less oxygenated, and therefore less polar, than an AlN layer not exposed to the pre-treatment process of the present disclosure.

The pre-treatment process facilitates adhesion of the a-Si film directly onto the AlN layer without an intermediate adhesion layer. Further, in some examples, the pre-treatment process may be performed in a same processing chamber as the deposition of the a-Si film, in a same processing chamber as the deposition of the AlN layer, etc. without breaking vacuum.

Accordingly, the pre-treatment process may be configured to eliminate the need for multi-chamber or multi-tool processing, reducing both cost and processing time associated with depositing the intermediate adhesion layer. Further, removing the intermediate adhesion layer from the structure of the AlN layer and the a-Si film reduces interface boundaries that may potentially inhibit or degrade phonon transduction for acoustic or thermal propagation during subsequent processing steps and/or degrade performance or characterization of the manufactured device.

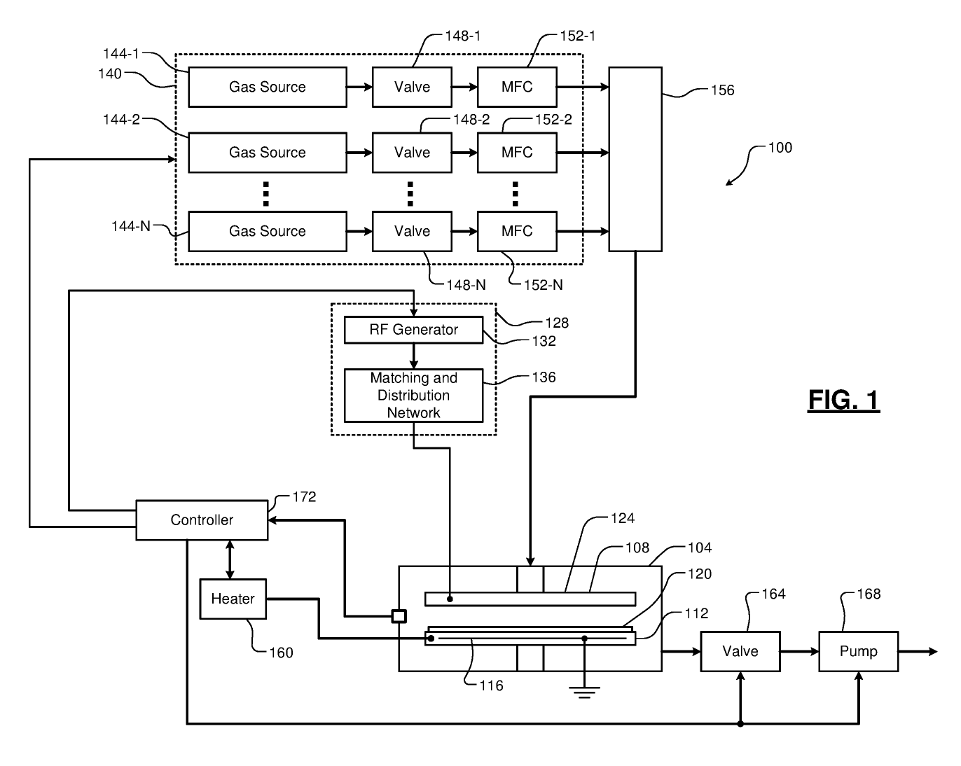

Referring now to FIG. 1, an example of a substrate processing system 100 for performing the pre-treatment process and deposition of an a-Si film on an AlN layer according to the principles of the present disclosure is shown. While the foregoing example relates to PECVD systems, other plasma-based substrate processing chambers may be used. While the present disclosure describes performing the pre-treatment process and deposition of the a-Si film a same processing chamber, two or more separate processing chambers may be used while nonetheless maintaining the substrate in a controlled vacuum environment without exposure to atmospheric conditions.

The substrate processing system 100 includes a processing chamber 104 that encloses other components of the substrate processing system 100 and contains the RF plasma when used. The substrate processing system 100 includes an upper electrode 108 and a substrate support such as a pedestal 112. In this example, the pedestal corresponds to a lower electrode 116. A substrate 120 is arranged on the pedestal 112 between the upper electrode 108 and the lower electrode 116. For example, the substrate 120 may include an AlN layer as described below in more detail.

For example only, the upper electrode 108 may include a showerhead 124 that introduces and distributes process gases. Alternately, the upper electrode 108 may include a conducting plate and the process gases may be introduced in another manner. The lower electrode 116 may be arranged in a non-conductive pedestal. Alternately, the pedestal 112 may include an electrostatic chuck that includes a conductive plate that acts as the lower electrode 116.

An RF generating system 128 generates and outputs an RF voltage to one of the upper electrode 108 and the lower electrode 116 when plasma is used. The other one of the upper electrode 108 and the lower electrode 116 may be DC grounded, AC grounded or floating. For example only, the RF generating system 128 may include an RF voltage generator 132 that generates the RF voltage that is fed by a matching and distribution network 136 to the upper electrode 108 or the lower electrode 116.

An example gas delivery system 140 includes one or more gas sources 144-1, 144-2, . . . , and 144-N (collectively gas sources 144), where N is an integer greater than zero. The gas sources 144 supply one or more gases (e.g., precursors, reactants, inert gases, etc.) and mixtures thereof. Vaporized precursor may also be used. At least one of the gas sources 144 may contain gases used in the pre-treatment process of the present disclosure (e.g., NH₃, N₂, etc.). The gas sources 144 are connected by valves 148-1, 148-2, . . . , and 148-N (collectively valves 148) and mass flow controllers 152-1, 152-2, . . . , and 152-N (collectively mass flow controllers 152) to a manifold 156. An output of the manifold 156 is fed to the processing chamber 104. For example only, the output of the manifold 156 is fed to the showerhead 124.

A heater 160 may be connected to a heater coil (not shown) arranged in the pedestal 112 to heat the pedestal 112. The heater 160 may be used to control a temperature of the pedestal 112 and the substrate 120. A valve 164 and pump 168 may be used to evacuate reactants from the processing chamber 104. A controller 172 may be used to control various components of the substrate processing system 100. For example only, the controller 172 may be used to control flow of process, carrier and precursor gases, striking and extinguishing plasma, removal of reactants, monitoring of chamber parameters, etc. The controller 172 according to the principles of the present disclosure is further configured to implement the pre-treatment process of the substrate 120 prior to depositing an a-Si film on an AlN layer of the substrate 120 as described below in more detail.

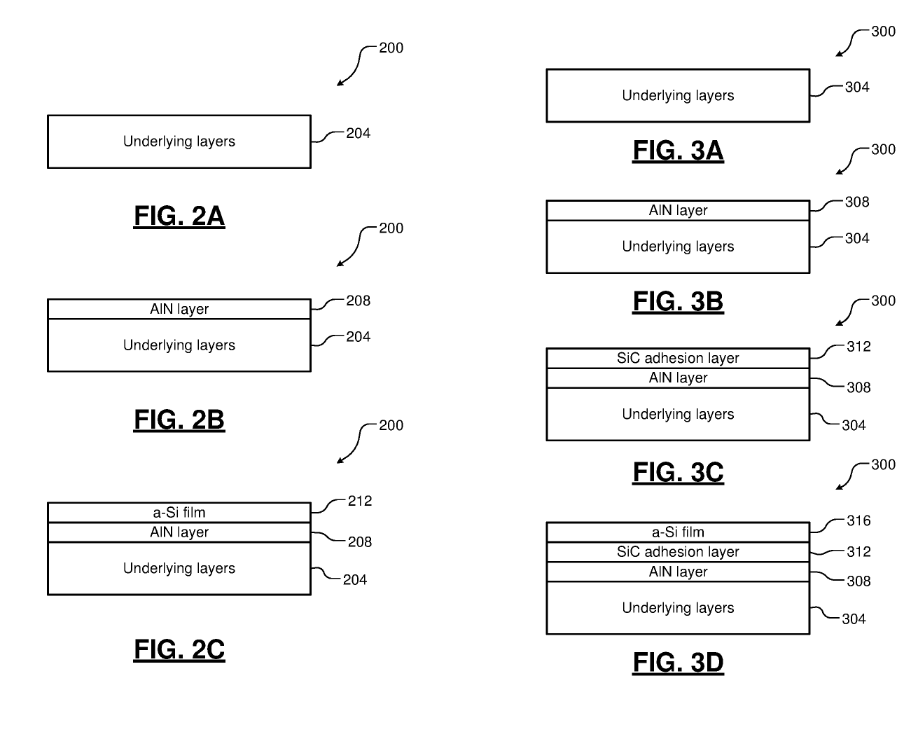

Referring now to FIGS. 2A, 2B, and 2C, an example a-Si deposition process is shown. FIG. 2A shows an example substrate 200 provided for processing. For example, the substrate 200 may include one or more underlying layers 204. FIG. 2B shows an AlN layer 208 deposited on the underlying layers 204. FIG. 2C shows an a-Si film 212 deposited directly on the AlN layer 208. In other words, the a-Si film 212 is deposited directly on the AlN layer 208 without depositing an intermediate adhesion layer on the AlN layer 208. In this example, the a-Si film 212 may delaminate (i.e., separate) from the AlN layer 208.

Referring now to FIGS. 3A, 3B, 3C, and 3D, another example a-Si deposition process is shown. FIG. 3A shows an example substrate 300 provided for processing. For example, the substrate 300 may include one or more underlying layers 304. FIG. 3B shows an AlN layer 308 deposited on the underlying layers 304. FIG. 3C shows an intermediate adhesion layer (e.g., a silicon carbide, or SiC layer) 312 deposited on the AlN layer 308. FIG. 3D shows an a-Si film 316 deposited on the intermediate adhesion layer 312. In this example, the intermediate adhesion layer 312 facilitates adhesion of the a-Si film 316 to the AlN layer 308. However, the additional step of depositing the intermediate adhesion layer 312 increases cost and processing time. For example, deposition of the intermediate adhesion layer 312 may require transfer of the substrate 300 to a different processing chamber (i.e., a different processing chamber than a processing chamber used to deposit the a-Si film 316), consumption of additional process gases and other materials, etc.

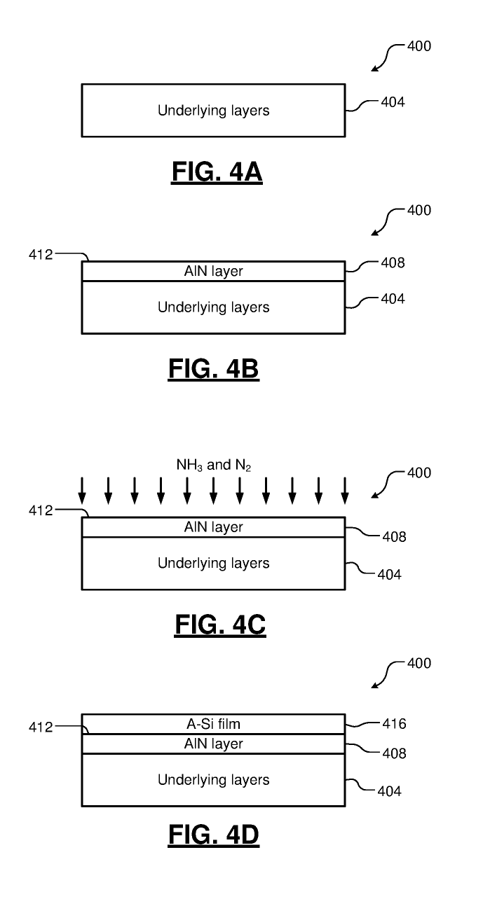

Referring now to FIGS. 4A, 4B, 4C, and 4D, an example a-Si deposition process including a pre-treatment process according to the principles of the present disclosure is shown. FIG. 4A shows an example substrate 400 provided for processing. For example, the substrate 400 may include one or more underlying layers 404. FIG. 4B shows an AlN layer 408 deposited on the underlying layers 404. FIG. 4C shows a pre-treatment process applied to the AlN layer 408. For example, the pre-treatment process includes supplying a gas mixture including NH₃ gas and N₂ gas to an upper surface 412 of the AlN layer 408 and igniting plasma within the processing chamber to condition the AlN layer 408 such that oxygen, oxide, and/or other deposition residue remaining on the upper surface 412 of the AlN layer 408 are removed.

FIG. 4D shows an a-Si film 416 deposited directly onto the AlN layer 408. In this example, the pre-treatment process shown in FIG. 4C facilitates adhesion of the a-Si film 416 directly onto the AlN layer 408 without an intermediate adhesion layer. Further, the pre-treatment process may be performed in a same processing chamber as the deposition of the a-Si film 416 (i.e., in situ, without removing the substrate 400 from the processing chamber between the application of the pre-treatment process and the deposition of the a-Si film 416). In some examples, the pre-treatment process may be performed in a same processing chamber as the deposition of the AlN layer 408.

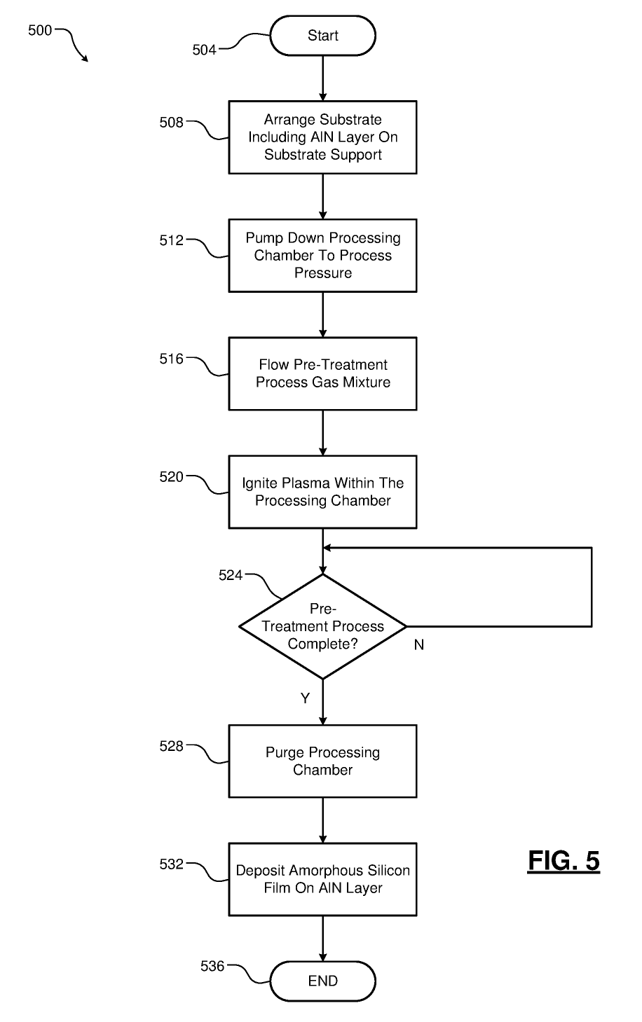

Referring now to FIG. 5, an example method 500 of performing a pre-treatment process of an AlN and deposition of a-Si film according to the present disclosure begins at 504. At 508, a substrate including an AlN layer is arranged on a substrate support. For example, the substrate is arranged on the pedestal 112 in the processing chamber 104 as shown in FIG. 1. In one example, the AlN layer is deposited on the substrate prior to the substrate being arranged on the pedestal 112 (e.g., the AlN layer is deposited on the substrate in a processing chamber other than the processing chamber 104 and then transferred to the processing chamber 104). In another example, the AlN layer is deposited on the substrate in the processing chamber 104.

At 512, the method 500 (e.g., the controller 172, and/or components of the substrate processing system 100 responsive to commands from the controller 172) pumps down the processing chamber 104 to a process pressure. For example, the process pressure corresponds to a desired process pressure for the pre-treatment process. In one example, the pressure is between 1 and 4 torr. At 516, the method 500 (e.g., the controller 172) flows a pre-treatment process gas mixture into the processing chamber 104. For example, the pre-treatment process gas mixture may include NH₃ gas and N₂ gas. In other examples, argon (Ar) gas and/or helium (He) gas may be provided in addition to or instead of the N₂ gas. A flow rate of the NH₃ gas may be between 2000 and 6000 standard cubic centimeters per minute (sccm) while a flow rate of the N₂ gas is between 500 and 3000 sccm. At 520, the method 500 (e.g., the controller 172) ignites plasma within the processing chamber 104. In one example, such as in a substrate processing system including a high frequency RF power source and a low frequency RF power source, the high frequency RF power is between 500 and 1000 W and the low frequency RF power is between is between 200 and 600 W. In other examples, a single RF power source (i.e., instead of both high frequency and low frequency RF power sources) may be used to provide power between 700 and 1600 W.

At 524, the method 500 (e.g., the controller 172) determines whether the pre-treatment process is complete. For example, the pre-treatment process may continue for a predetermined period to remove residual contaminants on a surface of the AlN layer, including, but not limited to, oxygen/oxide and AlN particles as described above. In some examples, the predetermined period is between 10 and 60 seconds. If true, the method 500 continues to 528. If false, the method 500 continues to 524. At 528, the method 500 (e.g., the controller 172) purges the processing chamber 104 to remove materials remaining from the pre-treatment process. At 532, the method 500 (e.g., the controller 172) deposits an a-Si film on the AlN layer of the substrate within the processing chamber 104. In one example, the a-Si film is deposited on the AlN layer in the same processing chamber 104 used to perform 508, 512, 516, and 520. The method 500 ends at 536.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” “underlying” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A method for depositing an amorphous film, the method comprising:
providing, in a substrate processing chamber, a substrate including an aluminum nitride layer;
performing a pre-treatment process to condition an upper surface of the aluminum nitride layer, wherein performing the pre-treatment process includes
supplying a gas mixture into the substrate processing chamber, wherein the gas mixture includes ammonia, and
activating plasma within the substrate processing chamber to condition the upper surface of the aluminum nitride layer; and
depositing the amorphous film onto the aluminum nitride layer.

2. The method of claim 1, wherein the amorphous film is amorphous silicon.

3. The method of claim 1, wherein the gas mixture further includes a non-reactive gas.

4. The method of claim 3, wherein the non-reactive gas is non-destructive to aluminum nitride.

5. The method of claim 3, wherein the non-reactive gas includes at least one of molecular nitrogen gas, argon gas, and helium gas.

6. The method of claim 1, wherein conditioning the upper surface of the aluminum nitride layer includes removing material including at least one of residual deposition material, atmospheric contamination, and native oxides from the upper surface.

7. The method of claim 6, wherein activating the plasma causes the gas mixture to react with the material.

8. The method of claim 7, wherein activating the plasma causes the gas mixture to react with the material to form molecules with (i) at least one of nitrogen and hydrogen and (ii) components of the material.

9. The method of claim 7, wherein the material includes at least one of oxygen and carbon.

10. The method of claim 7, further comprising purging the substrate processing chamber subsequent to performing the pre-treatment process and prior to depositing the amorphous film.

11. A system for depositing an amorphous film, the system comprising:
a gas delivery system configured to provide one or more gases to a substrate processing chamber;
a radio frequency (RF) generating system configured to activate plasma within the substrate processing chamber; and
a controller configured to
perform a pre-treatment process to condition an upper surface of an aluminum nitride layer of a substrate, wherein, to perform the pre-treatment process, the controller is further configured to
control the gas delivery system to supply a gas mixture into the substrate processing chamber, wherein the gas mixture includes ammonia, and
control the RF generating system to activate plasma within the substrate processing chamber to condition the upper surface of the aluminum nitride layer, and
control the gas delivery system to deposit the amorphous film onto the aluminum nitride layer.

12. The system of claim 11, wherein the amorphous film is amorphous silicon.

13. The system of claim 11, wherein the gas mixture further includes a non-reactive gas.

14. The system of claim 13, wherein the non-reactive gas is non-destructive to aluminum nitride.

15. The system of claim 13, wherein the non-reactive gas includes at least one of molecular nitrogen gas, argon gas, and helium gas.

16. The system of claim 11, wherein conditioning the upper surface of the aluminum nitride layer includes removing material including at least one of residual deposition material, atmospheric contamination, and native oxides from the upper surface.

17. The system of claim 16, wherein activating the plasma causes the gas mixture to react with material on the upper surface of the aluminum nitride layer.

18. The system of claim 17, wherein activating the plasma causes the gas mixture to react with the material to form molecules with (i) at least one of nitrogen and hydrogen and (ii) components of the material.

19. The system of claim 17, wherein the material includes at least one of oxygen and carbon.

20. The system of claim 17, wherein the controller is further configured to control purging of the substrate processing chamber subsequent to performing the pre-treatment process and prior to depositing the amorphous film.
